(19) United States
(12) Patent Application Publication
(10) Pub. No.: US 2022/0238727 A1
(43) Pub. Date: Jul. 28, 2022

(54) ZENER DIODE AND MANUFACTURING METHOD THEREOF

(71) Applicant: RICHTEK TECHNOLOGY CORPORATION, Zhubei City (TW)

(72) Inventors: Ting-Wei Liao, Taichung (TW); Chien-Yu Chen, Kaohsiung (TW); Kun-Huang Yu, Hsinchu (TW); Wu-Te Weng, Hsinchu (TW); Chien-Wei Chiu, Yunlin (TW); Ta-Yung Yang, Taoyuan (TW)

(21) Appl. No.: 17/571,401

(22) Filed: Jan. 7, 2022

Related U.S. Application Data
(60) Provisional application No. 63/140,615, filed on Jan. 22, 2021.

(30) Foreign Application Priority Data
Jun. 3, 2021 (TW) 110120191

(51) Int. Cl. H01L 29/866; H01L 29/78; H01L 29/06; H01L 29/66

(52) U.S. Cl. CPC H01L 29/866; H01L 29/7821; H01L 29/4238; H01L 29/66106; H01L 29/66704; H01L 29/0626

(57) ABSTRACT

The present invention provides a Zener diode and a manufacturing method thereof. The Zener diode includes: a semiconductor layer, an N-type region, and a P-type region. The N-type region has N-type conductivity, wherein the N-type region is formed in the semiconductor layer beneath an upper surface of the semiconductor layer, and in contact with the upper surface. The P-type region has P-type conductivity, wherein the P-type region is formed in the semiconductor layer and is completely beneath the N-type region, and in contact with the N-type region. The N-type region overlays the entire P-type region. The N-type region has an N-type conductivity dopant concentration, wherein the N-type conductivity dopant concentration is higher than a P-type conductivity dopant concentration of the P-type region.

### CROSS REFERENCE

The present invention claims priority to U.S. 63/140615 filed on Jan. 22, 2021 and claims priority to TW 110120191 filed on Jun. 3, 2021.

### BACKGROUND OF THE INVENTION

### Field of Invention

The present invention relates to a Zener diode and a manufacturing method of a Zener diode; particularly, it relates to a Zener diode having enhanced stability and reliability of Zener breakdown voltage and a manufacturing method of such a Zener diode.

### Description of Related Art

Please refer to FIG. 1A and FIG. 1B. FIG. 1A shows a schematic diagram of a cross-section view of a conventional Zener diode 100, whereas, FIG. 1B shows a schematic diagram of a partial enlarged view of the conventional Zener diode 100. As shown in FIG. 1A and FIG. 1B, the conventional Zener diode 100 comprises: a semiconductor layer 12, isolation regions 14 and 14′, a P-type region 15, an N-type region 16, polysilicon layers 17 and 17′ and P-type contacts 18 and 18′. The semiconductor layer 12 is formed on a substrate 11. The P-type region 15 and the P-type contacts 18 and 18′ have P-type conductivity. The N-type region 16 has N-type conductivity. The polysilicon layers 17 and 17′ are formed on the semiconductor layer 12 and serve to define the N-type region 16.

Please refer to FIG. 1B, which shows a schematic diagram of a partial enlarged view of the P-type region 15 and the N-type region 16 in the conventional Zener diode 100. Generally, a Zener breakdown of the conventional Zener diode 100 occurs at a boundary of the P-type region 15 and the N-type region 16, wherein such boundary of the P-type region 15 and the N-type region 16 is near to a vicinity of an upper surface 12a of the semiconductor layer 12, as shown by the breakdown zone in FIG. 1B. Because the lattice arrangement of the vicinity of the upper surface 12a of the semiconductor layer 12 is irregular (as compared to the lattice arrangement of the rest regions of the semiconductor layer 12) and because the vicinity of the upper surface 12a of the semiconductor layer 12 tends to suffer impurity contamination, the level of the Zener breakdown voltage will be affected. As a result, although under a same manufacture process, different Zener diodes have different Zener breakdown voltages. Such variation undesirably jeopardizes the reliability of the electronic characteristics of the conventional Zener diode 100.

In a case when the N-type region 16 of the conventional Zener diode 100 is electrically connected to a positive voltage and the P-type region 15 of the conventional Zener diode 100 is electrically connected to a negative voltage, when a voltage difference between the positive voltage and the negative voltage is increased, the temperature correspondingly increases, and the vibration magnitude of the lattice correspondingly increases, whereby a Zener breakdown occurs in a depletion region, and the conventional Zener diode 100 will operate under a Zener breakdown condition. However as mentioned above, because of the lattice arrangement and impurity contamination problems at the vicinity of the upper surface 12a of the semiconductor layer 12, Zener breakdown voltage of the conventional Zener diode 100 is unstable, which undesirably limits its safe operation area (SOA). The definition of SOA is well known to those skilled in the art, so the details thereof are not redundantly explained here.

In view of the above, to overcome the drawback in the prior art, the present invention proposes a Zener diode and a manufacturing method thereof, which is capable of enhancing the stability of the Zener breakdown voltage and enhancing the SOA.

### SUMMARY OF THE INVENTION

From one perspective, the present invention provides a Zener diode, comprising: a semiconductor layer, which is formed on a substrate; an N-type region having N-type conductivity, wherein the N-type region is formed in the semiconductor layer, wherein the N-type region is beneath and in contact with an upper surface of the semiconductor layer; and a P-type region having P-type conductivity, wherein the P-type region is formed in the semiconductor layer, wherein the P-type region is completely beneath and in contact with the N-type region; wherein the N-type region overlays the entire P-type region; wherein an N-type conductivity dopant concentration of the N-type region is higher than a P-type conductivity dopant concentration of the P-type region.

From another perspective, the present invention provides a manufacturing method of a Zener diode, comprising: forming a semiconductor layer on a substrate; forming a P-type region in the semiconductor layer, wherein the P-type region has P-type conductivity; forming an N-type region in the semiconductor layer, wherein the N-type region has N-type conductivity, wherein the N-type region is beneath and in contact with an upper surface of the semiconductor layer, and wherein the P-type region is completely beneath and in contact with the N-type region; wherein the N-type region overlays the entire P-type region; wherein an N-type conductivity dopant concentration of the N-type region is higher than a P-type conductivity dopant concentration of the P-type region.

In one embodiment, the Zener diode further comprises: a first well having N-type conductivity, wherein the first well is formed in the semiconductor layer, and wherein in the semiconductor layer, the first well encompasses and contacts the P-type region; a second well having P-type conductivity, wherein the second well is formed in the semiconductor layer, and wherein in the semiconductor layer, the second well encompasses and contacts the first well; and a deep well having P-type conductivity, wherein the deep well is formed in the semiconductor layer, and wherein the deep well is vertically beneath and in contact with the P-type region and the first well, and wherein a bottom of the P-type region and a bottom of the first well are entirely covered by the deep well from below.

In one embodiment, the Zener diode further comprises: a third well having N-type conductivity, wherein the third well is formed in the semiconductor layer, and wherein in the semiconductor layer, the third well encompasses and contacts the second well; a fourth well having P-type conductivity, wherein the fourth well is formed in the semiconductor layer, and wherein in the semiconductor layer, the fourth well encompasses and contacts the third well; and a buried layer having N-type conductivity, wherein the buried layer is formed in the semiconductor layer, and wherein the buried layer is vertically beneath and in contact with the deep well, the second well and the third well, and wherein a bottom of the deep well, a bottom of the second well and a bottom of the third well are entirely covered by the buried layer from below.

In one embodiment, the Zener diode further comprises: a polysilicon layer, which is formed on and in contact with the semiconductor layer, wherein the polysilicon layer serves to define the N-type region, wherein from a top view, the polysilicon layer encompasses the N-type region from outside.

In one embodiment, the Zener diode further comprises: an isolation region, which is formed in the semiconductor layer, wherein the isolation region is an insulator, and wherein from a top view, the isolation region lies between the first well and the second well.

In one embodiment, the step of forming the P-type region in the semiconductor layer includes: forming a polysilicon layer, to define a first implantation region, wherein the first implantation region serves to define the P-type region; and adopting the polysilicon layer as a mask, and implanting the P-type conductivity impurities into the first implantation region in the form of accelerated ions via a first ion implantation process step.

In one embodiment, the step of forming the N-type region in the semiconductor layer includes: etching a polysilicon layer via an etching process step, to define a second implantation region, wherein the second implantation region serves to define the N-type region; and adopting the etched polysilicon layer as a mask, and implanting the N-type conductivity impurities into the second implantation region in the form of accelerated ions via a second ion implantation process step.

The objectives, technical details, features, and effects of the present invention will be better understood with regard to the detailed description of the embodiments below, with reference to the attached drawings.

### BRIEF DESCRIPTION OF THE DRAWINGS

FIG. 1A shows a schematic diagram of a cross-section view of a conventional Zener diode.

FIG. 1B shows a schematic diagram of a partial enlarged view of a conventional Zener diode.

FIG. 2A shows a schematic diagram of a cross-section view of a Zener diode according to an embodiment of the present invention.

FIG. 2B shows a schematic diagram of a partial enlarged view of a Zener diode according to an embodiment of the present invention.

FIG. 3A shows a schematic diagram of a top view of a Zener diode according to an embodiment of the present invention.

FIG. 3B shows a schematic diagram of a cross-section view of a Zener diode according to an embodiment of the present invention.

FIG. 4A shows a schematic diagram of a top view of a Zener diode according to an embodiment of the present invention.

FIG. 4B shows a schematic diagram of a cross-section view of a Zener diode according to an embodiment of the present invention.

FIG. 5A to FIG. 5I show schematic diagrams of a manufacturing method of a Zener diode according to an embodiment of the present invention.

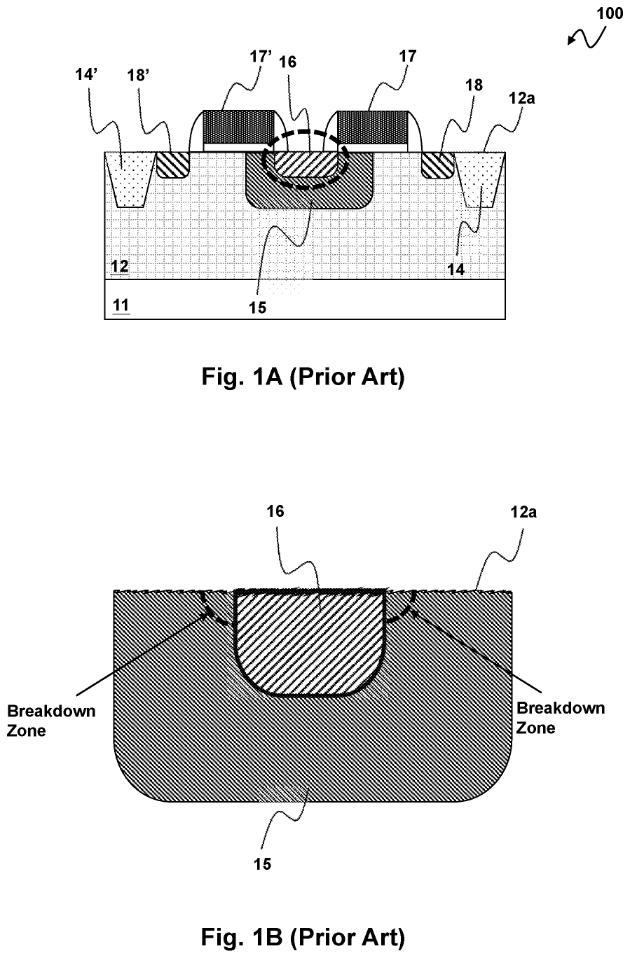

### DESCRIPTION OF THE PREFERRED EMBODIMENTS

The drawings as referred to throughout the description of the present invention are for illustration only, to show the interrelations among the process steps and the layers, but the shapes, thicknesses, and widths are not drawn in actual scale.

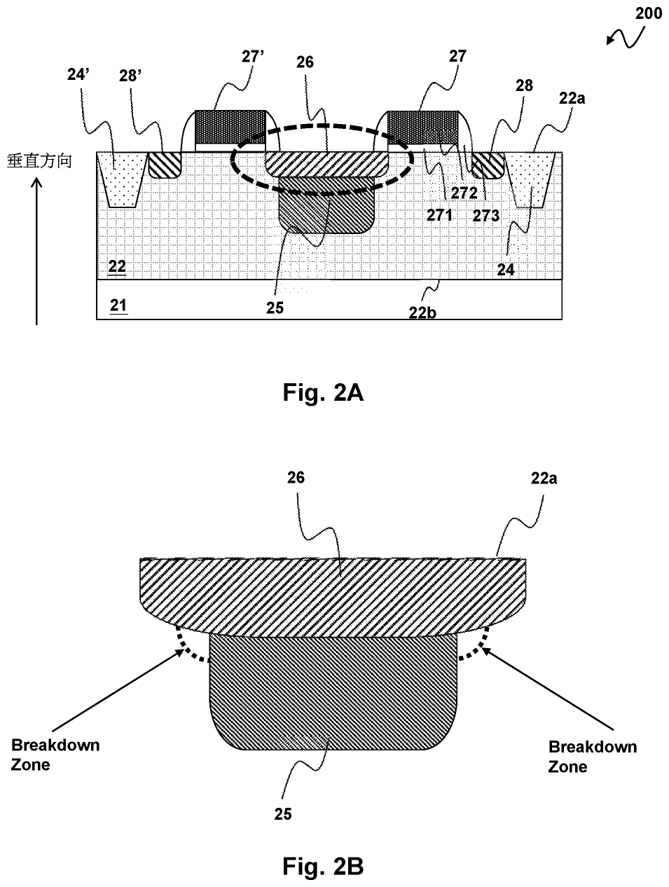

Please refer to FIG. 2A and FIG. 2B. FIG. 2A shows a schematic diagram of a cross-section view of a Zener diode according to an embodiment of the present invention, whereas, FIG. 2B shows a schematic diagram of a partial enlarged view of a Zener diode according to an embodiment of the present invention. As shown in FIG. 2A, the Zener diode 200 comprises: a semiconductor layer 22, isolation regions 24 and 24′, a P-type region 25, an N-type region 26, polysilicon layers 27 and 27′ and P-type contacts 28 and 28′. The semiconductor layer 22 is formed on a substrate 21. The P-type region 25 and the P-type contacts 28 and 28′ have P-type conductivity. The N-type region 26 has N-type conductivity. The polysilicon layers 27 and 27′ are formed on the semiconductor layer 22 and serve to define the N-type region 26.

The semiconductor layer 22 is formed on the substrate 21. The semiconductor layer 22 has a top surface 22a and a bottom surface 22b opposite to the top surface 22a in a vertical direction (as indicated by the direction of the solid arrow in FIG. 2A) . The substrate 21 is, for example but not limited to, a P-type or N-type semiconductor silicon substrate. The semiconductor layer 22, for example, is formed on the substrate 21 by an epitaxial process step, or is a part of the substrate 21. The semiconductor layer 22 can be formed by various methods known to a person having ordinary skill in the art, so the details thereof are not redundantly explained here. In this embodiment, the semiconductor layer 22 has P-type conductivity.

Please still refer to FIG. 2A. The isolation regions 24 and 24′ are formed on and in contact with the top surface 22a. In this embodiment, the isolation regions 24 and 24′ serve to define a main operation area of the Zener diode 200 and serve to electrically isolate the Zener diode 200 from other devices on the substrate 21. The isolation regions 24 and 24′ have for example but not limited to a shallow trench isolation (STI) structure as shown in the figure, or may have a chemical vapor deposition (CVD) structure or a local oxidation of silicon (LOCOS) structure. The LOCOS structure, the STI structure and the CVD structure can be formed by corresponding methods known to a person having ordinary skill in the art, so the details thereof are not redundantly explained here.

The N-type region 26 has N-type conductivity and is formed in the semiconductor layer 22. The N-type region 26 is located beneath the top surface 22a and is in contact with the top surface 22a in the vertical direction. The P-type region 25 has P-type conductivity and is formed in the semiconductor layer 22. The P-type region 25 is completely beneath and in contact with the N-type region 26 in the vertical direction. The N-type region 26 overlays the entire P-type region 25. An N-type conductivity dopant concentration of the N-type region 26 is higher than a P-type conductivity dopant concentration of the P-type region 25. In the vertical direction, the N-type region 26 extends downwardly from the top surface 22a, whereas, the P-type region 25 extends downwardly from a bottom of the N-type region 26. The P-type contacts 28 and 28′ have P-type conductivity and serve as electrical contacts of the P-type region 25.

Please still refer to FIG. 2B, which shows a schematic diagram of a partial enlarged view of the P-type region 25 and the N-type region 26 in the Zener diode 200. The Zener diode 200 of the present invention is different from the prior art Zener diode 100, in that: the Zener breakdown of the Zener diode 200 occurs at a boundary where the P-type region 25 intersects with the N-type region 26. In contrast, the Zener breakdown of the prior art Zener diode 100 occurs at a boundary of the P-type region 15 and the N-type region 16, which is near to a vicinity of an upper surface 12a of the semiconductor layer 12. To be more specific, the Zener breakdown of the Zener diode 200 of this embodiment occurs at a boundary where the P-type region 25 intersects with the N-type region 26, as shown by the breakdown zone in FIG. 2B; in other words, the Zener breakdown of the Zener diode 200 of the present invention occurs at a location which corresponds to a depth of the downward extension of the N-type region 26 from the top surface 22a. Because the lattice arrangement of a deeper location within the semiconductor layer 22 is relatively more regular as compared to the lattice arrangement of the vicinity of the upper surface 12a of the semiconductor layer 12 in prior art and because a deeper location within the semiconductor layer 22 has less serious impurity contamination problem, the level of the Zener breakdown voltage of the Zener diode 200 of the present invention is more stable and reliable. That is, under a same manufacture process, although different Zener diodes may have different Zener breakdown voltages, the difference between Zener breakdown voltages of different Zener diodes is significantly reduced, so the reliability of the electronic characteristics of the Zener diode 200 of the present invention is significantly increased.

In a case when the N-type region 26 of the Zener diode 200 is electrically connected to a positive voltage and the P-type region 25 of the Zener diode 200 is electrically connected to a negative voltage, when a voltage difference between the positive voltage and the negative voltage is increased, the temperature correspondingly increases, and the vibration magnitude of the lattice correspondingly increases, whereby a Zener breakdown occurs in a depletion region, and the conventional Zener diode 200 will operate under a Zener breakdown condition. However as compared to the prior art wherein the Zener breakdown occurs near the upper surface 22a of the semiconductor layer 22, the Zener breakdown in the present invention occurs at a location at a depth of downward extension of the N-type region 26 from the top surface 22a, and such location has less flawed lattice arrangement and less serious impurity contamination problem; hence, the Zener diode 200 of the present invention has a much more stable Zener breakdown voltage and better safe operation area (SOA).

In other words, as compared to the prior art, the present invention moves the the location where the Zener breakdown occurs from the top surface 22a of the semiconductor layer 22 downward to a deeper location within the semiconductor layer 22 where the lattice arrangement is relatively more regular and impurity contamination problem is less serious, when the Zener diode 200 is required to operate under a Zener breakdown condition, the Zener diode 200 will have a more stable and more reliable Zener breakdown voltage, providing a better performance and thus broadening the application scope of the Zener diode 200 of the present invention.

Note that the top surface 22a as referred to does not mean a completely flat plane but refers to the surface of the semiconductor layer 22, as indicated by a thick line in FIG. 2A. In the present embodiment, for example, a part of the top surface 22a where the isolation regions 24 and 24′ are in contact with has a recessed portion.

Note that the polysilicon layer 27 and a gate of another device which is also formed on the top surface 22a of the semiconductor layer 22 can be formed by a same process step. In this case, the gate includes a dielectric layer 271 which is in contact with the top surface 22a, a conductive layer 272, and a spacer layer 273 which is electrically insulative, the details of which are well known to those skilled in the art, so the details thereof are not redundantly explained here. The polysilicon layer 27 can be formed together with the gate conductive layer 272 of the device, and in this case there is a dielectric layer below the polysilicon layer 27 and a spacer layer outside the polysilicon layer 27. In one embodiment, the polysilicon layer 27 serves to define the N-type region 26.

Note that the term “N-type conductivity” and the term “P-type conductivity” as may be used herein, refer to: in a Zener diode 200, dopants having different conductivity are doped in various semiconductor components (for example but not limited to the above-mentioned semiconductor layer, N-type region, P-type region, P-type contacts), so that various semiconductor components can have P-type conductivity or N-type conductivity. The N-type conductivity has conductivity opposite to conductivity of the P-type conductivity.

Besides, note that a “Zener diode” is an electronic device capable of stabilizing/clamping a voltage by its Zener breakdown voltage when a reverse voltage is applied onto this diode. A forward bias voltage of a Zener diode is the same as a forward bias voltage of a typical diode; however, its reverse breakdown voltage (referred to as Zener breakdown voltage) is far more greater than that of a typical diode, so a Zener diode can withstand a much higher voltage as compared to a typical diode in reverse operation, and such characteristic is often used for stabilizing/clamping a voltage.

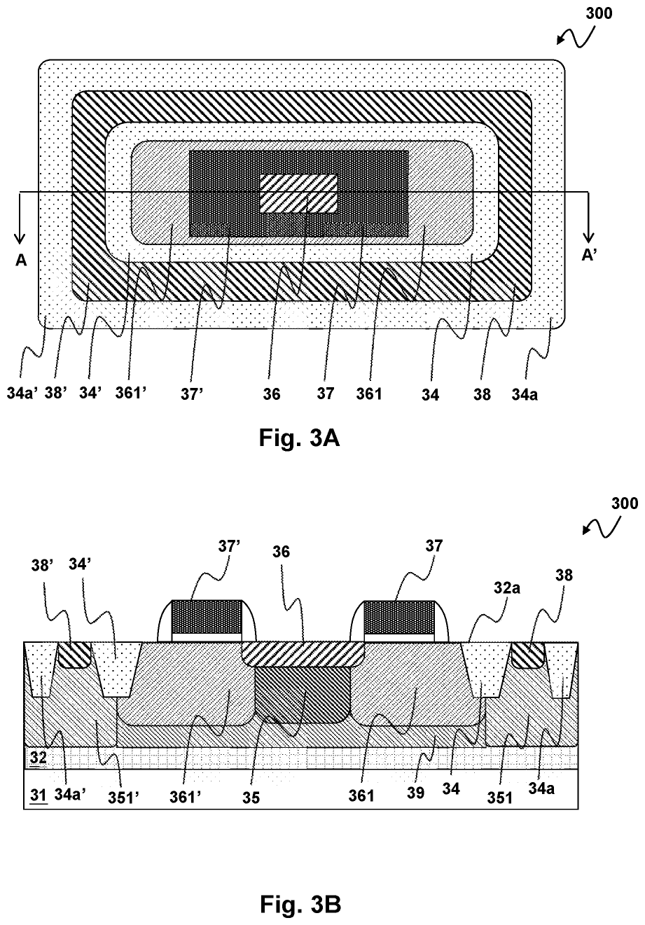

Please refer to FIG. 3A and FIG. 3B. FIG. 3A shows a schematic diagram of a top view of a Zener diode according to an embodiment of the present invention, whereas, FIG. 3B shows a schematic diagram of a cross-section view of a Zener diode according to an embodiment of the present invention taken along A-A′ line of FIG. 3A. In this embodiment, the Zener diode 300 is formed on the substrate 21. The Zener diode 300 comprises: a semiconductor layer 32, isolation regions 34 and 34′, a P-type region 35, an N-type region 36, polysilicon layers 37 and 37′, P-type contacts 38 and 38′, a deep well 39, first wells 361 and 361′ and second wells 351 and 351′.

This embodiment shown in FIG. 3A and FIG. 3B is different from the embodiment shown in FIG. 2A and FIG. 2B, in that: in this embodiment, in addition to a semiconductor layer 32, isolation regions 34 and 34′, a P-type region 35, an N-type region 36, polysilicon layers 37 and 37′, P-type contacts 38 and 38′, the Zener diode 300 further comprises: isolation regions 34a and 34a′, a deep well 39, first wells 361 and 361′ and second wells 351 and 351′.

Please still refer to FIG. 3A and FIG. 3B. In this embodiment, first wells 361 and 361′ have N-type conductivity, wherein the first wells 361 and 361′ are formed in the semiconductor layer 32. In the semiconductor layer 32, the first wells 361 and 361′ encompass and contact the P-type region 35. The first wells 361 and 361′ serve to electrically isolate the P-type region 35 and the first wells 361 and 361′ from the rest regions (other than the P-type region 35 and the first wells 361 and 361′) in the semiconductor layer 32.

Please still refer to FIG. 3A and FIG. 3B. In this embodiment, the second wells 351 and 351′ have P-type conductivity, wherein the second wells 351 and 351′ are formed in the semiconductor layer 32. In the semiconductor layer 32, the second wells 351 and 351′ encompass and contact the first wells 361 and 361′. The deep well 39 has P-type conductivity. The deep well 39 is formed in the semiconductor layer 32, and is vertically beneath and in contact with the P-type region 35 and the first wells 361 and 361′. Besides, a bottom of the P-type region 35 and bottoms of the first wells 361 and 361′ are entirely covered by the deep well 39 from below. In the semiconductor layer 32, the second wells 351 and 351′ and the deep well 39 encompass the first wells 361 and 361′, to electrically isolate the first wells 361 and 361′ from other regions in the semiconductor layer 32, and the second wells 351 and 351′ and the deep well 39 are electrically connected to the P-type region 35 and the P-type contacts 38 and 38′, so that the P-type contacts 38 and 38′ can serve as electrical contacts of the P-type region 35.

Please still refer to FIG. 3A and FIG. 3B. In this embodiment, polysilicon layers 37 and 37′ are formed on and in contact with the semiconductor layer 32. The polysilicon layers 37 and 37′ serve to define the N-type region 36.

Please still refer to FIG. 3A and FIG. 3B. From a top view of FIG. 3A, the polysilicon layers 37 and 37′, the first wells 361 and 361′, the isolation regions 34 and 34′, the P-type contacts 38 and 38′ and the isolation regions 34a and 34a′ have corresponding ring structures, respectively. The polysilicon layers 37 and 37′ encompass the N-type region 36 from outside.

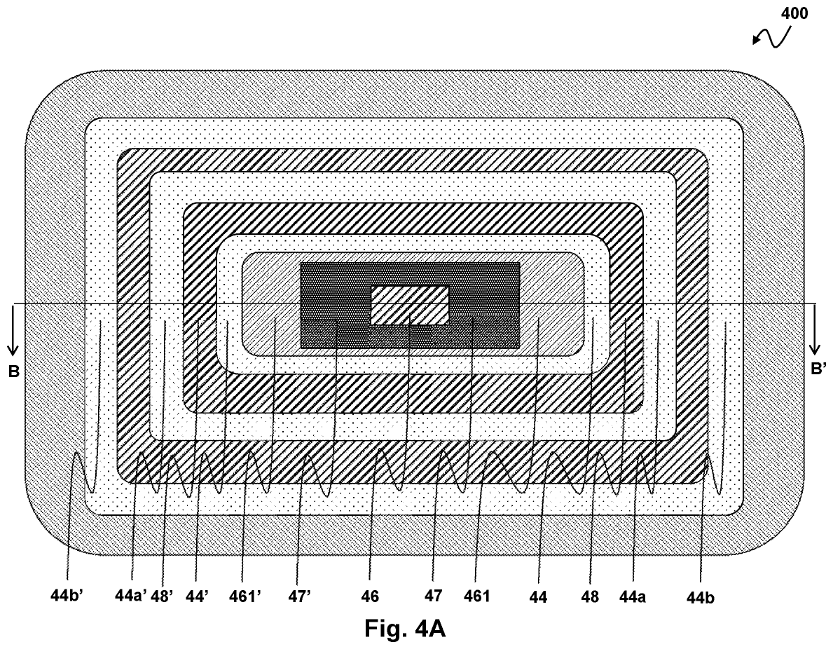

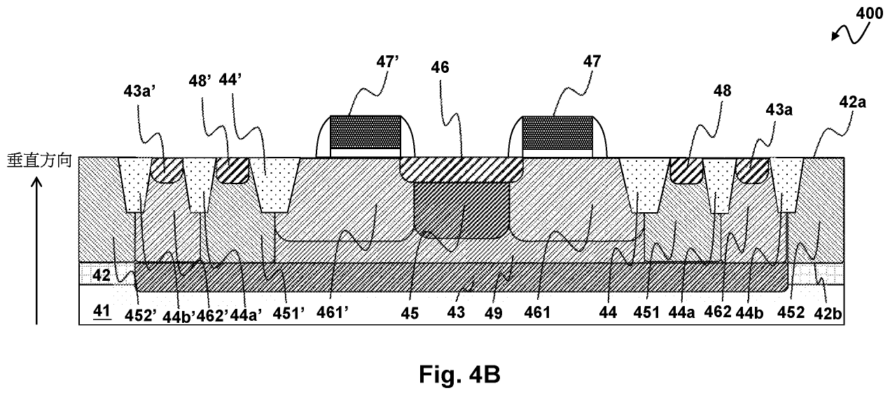

Please refer to FIG. 4A and FIG. 4B. FIG. 4A shows a schematic diagram of a top view of a Zener diode according to an embodiment of the present invention, whereas, FIG. 4B shows a schematic diagram of a cross-section view of a Zener diode according to an embodiment of the present invention taken along B-B′ line of FIG. 4A. In this embodiment, the Zener diode 400 comprises: a semiconductor layer 42, a buried layer 43, N-type contacts 43a and 43a′, isolation regions 44, 44′, 44a, 44a′, 44b, 44b′, a P-type region 45, an N-type region 46, polysilicon layers 47 and 47′, a deep well 39, first wells 461 and 461′, second wells 451 and 451′, third wells 462 and 462′ and fourth well 452 and 452′.

This embodiment shown in FIG. 4A and FIG. 4B is different from the embodiment shown in FIG. 3A and FIG. 3B, in that: in this embodiment, in addition to a semiconductor layer 42, isolation regions 44, 44′, 44a, 44a′, a P-type region 45, an N-type region 46, polysilicon layers 47 and 47′, a deep well 39, first wells 461 and 461′, second wells 451 and 451′, third wells 462 and 462′ and fourth well 452 and 452′, the Zener diode 400 further comprises: a buried layer 43, N-type contacts 43a and 43a′, isolation regions 44b, 44b′, third wells 462 and 462′ and fourth well 452 and 452′.

The third wells 462 and 462′ have N-type conductivity and are formed in the semiconductor layer 42. In the semiconductor layer 42, the third wells 462 and 462′ encompass and contact the second wells 451 and 451′. The fourth well 452 and 452′ have P-type conductivity and are formed in the semiconductor layer 42. In the semiconductor layer 42, the fourth well 452 and 452′ encompass and contact the third wells 462 and 462′. The buried layer 43 has N-type conductivity and the buried layer 43 is formed in the semiconductor layer 42. The buried layer 43 is vertically beneath and in contact with the deep well 49, the second wells 451 and 451′and the third wells 462 and 462′. A bottom of the deep well 49, bottoms of the second wells 451 and 451′ and bottoms of the third wells 462 and 462′ are entirely covered by the buried layer 43 from below. In the semiconductor layer 42, the third wells 462 and 462′ and the buried layer 43 encompass the second wells 451 and 451′ and the deep well 49, to electrically isolate the first wells 461 and 461′ from other regions in the semiconductor layer 42, and the third wells 462 and 462′ are electrically connected to the buried layer 43 and the N-type contacts 43a and 43a′, so that the N-type contacts 43a and 43a′ can serve as electrical contacts of the buried layer 43.

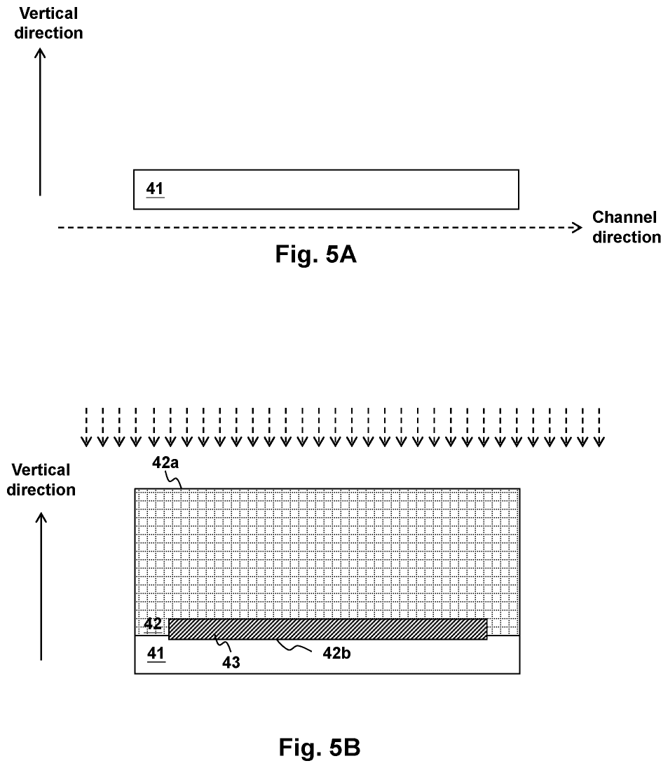

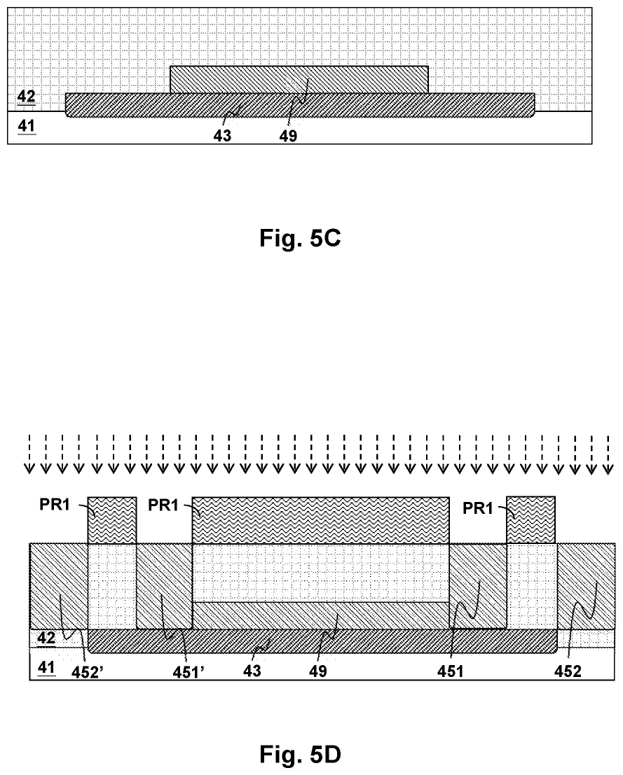

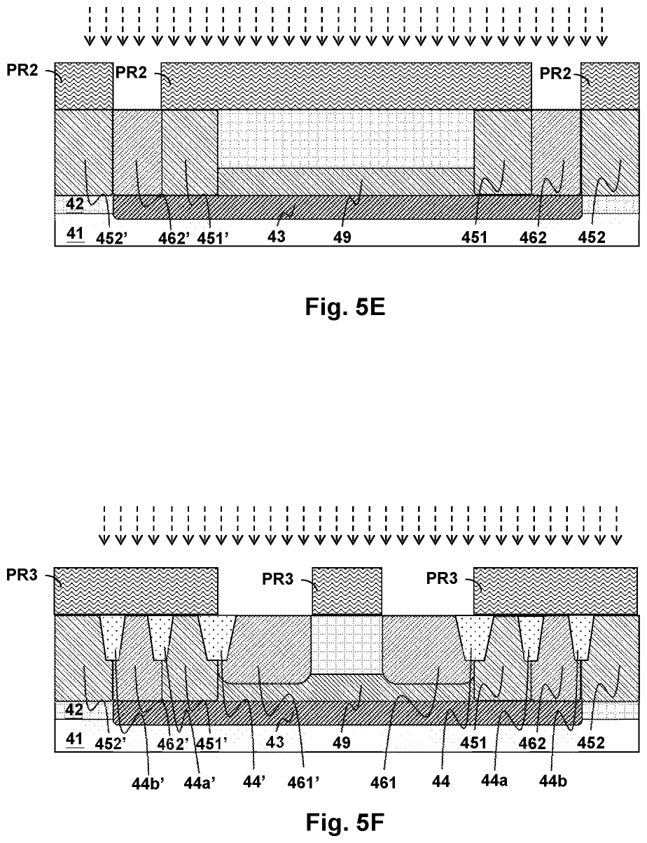

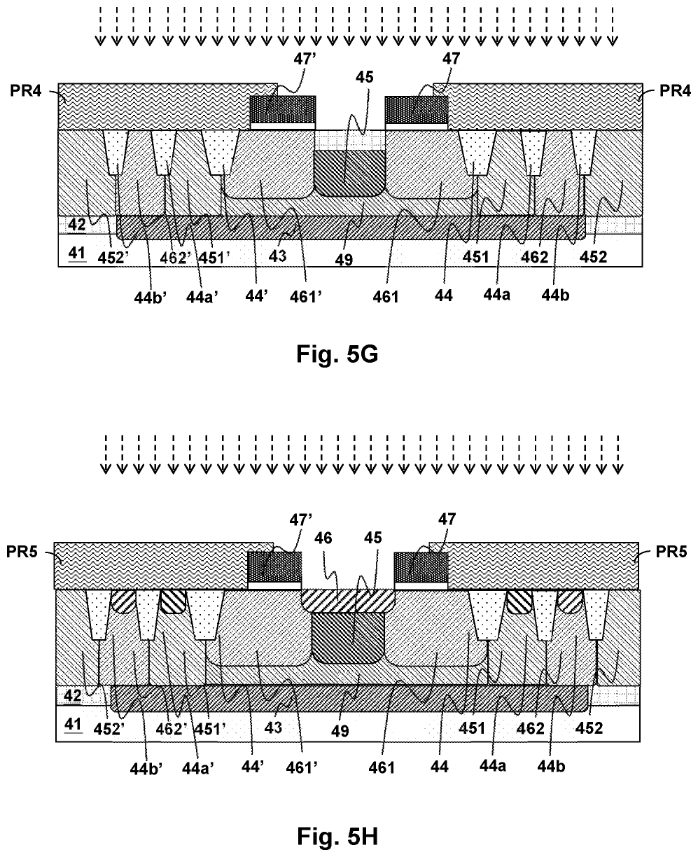

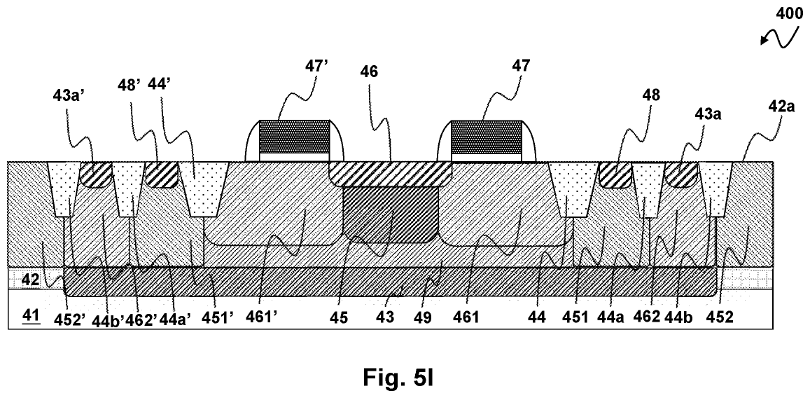

Please refer to FIG. 5A to FIG. 5I, which show schematic diagrams of a manufacturing method of a Zener diode 400 according to an embodiment of the present invention. As shown in FIG. 5A, firstly, a substrate 41 is provided. The substrate 41 is, for example but not limited to, a P-type or N-type semiconductor silicon substrate.

Next, referring to FIG. 5B, the semiconductor layer 42, for example, is formed on the substrate 41 by an epitaxial process step, or is a part of the substrate 41. The semiconductor layer 42 can be formed by various methods as known to a person having ordinary skill in the art, so the details thereof are not redundantly explained here. A buried layer 43 is formed in the semiconductor layer 42, wherein the buried layer 43 is vertically beneath and in contact with the deep well 49, the second wells 451 and 451′ and the third wells 462 and 462′ which are to be formed in later steps. Referring to FIG. 5E, a bottom of the deep well 49, bottoms of the second wells 451 and 451′ and bottoms of the third wells 462 and 462′ are entirely covered by the buried layer 43 from below. Referring back to FIG. 5B, in the vertical direction (as indicated by the solid arrow in FIG. 5B), the buried layer 43 is formed for example at two sides of a junction between the substrate 41 and the semiconductor layer 42; that is, a part of the buried layer 43 is located in the substrate 41, whereas, another part of the buried layer 43 is located in the semiconductor layer 42. The buried layer 43 has N-type conductivity and can be formed by, for example but not limited to, an ion implantation process step, wherein the ion implantation process step implants N-type conductivity impurities into the substrate 41 in the form of accelerated ions (as indicated by the dashed arrow in FIG. 5B), and a subsequent thermal diffusion step. The semiconductor layer 42 is formed on the substrate 41. The semiconductor layer 42 has a top surface 42a and a bottom surface 42b opposite to the top surface 42a in the vertical direction.

Next, referring to FIG. 5C, a deep well 49 is formed in the semiconductor layer 42, wherein the deep well 49 is vertically beneath and in contact with the P-type region 45 and first wells 461 and 461′ which are to be formed in later steps, wherein a bottom of the P-type region 45 and bottoms of the first wells 461 and 461′ are entirely covered by the deep well 49 from below (referring to FIG. 5G). The deep well 49 has P-type conductivity. The deep well 49 has P-type conductivity and can be formed by, for example but not limited to, an ion implantation process step, wherein the ion implantation process step implant P-type conductivity impurities into the semiconductor layer 42 in the form of accelerated ions, to form the deep well 49.

Next, referring to FIG. 5D, second wells 451 and 451′ and fourth wells 452 and 452′ are formed in the semiconductor layer 42. The second wells 451 and 451′ have P-type conductivity. In the semiconductor layer 42, the second wells 451 and 451′ encompass and contact the first wells 461 and 461′ which are to be formed in later steps (referring to FIG. 5F). The fourth well 452 and 452′ have P-type conductivity. In the semiconductor layer 42, the fourth well 452 and 452′ encompass and contact the third wells 462 and 462′ which are to be formed in later steps (referring to FIG. 5E). The second wells 451 and 451′ and the fourth well 452 and 452′ can be formed by, for example but not limited to, a lithography process step and anion implantation process step, wherein the lithography process step includes forming a photo-resist layer PR1 as a mask, and the ion implantation process step implants P-type conductivity impurities into the semiconductor layer 42 in the form of accelerated ions (as indicated by the dashed arrow in FIG. 5D), to form the second wells 451 and 451′ and the fourth well 452 and 452′.

Next, referring to FIG. 5E, third wells 462 and 462′ are formed in the semiconductor layer 42. The third wells 462 and 462′ have N-type conductivity. In the semiconductor layer 42, the third wells 462 and 462′ encompass and contact the second wells 451 and 451′. The third wells 462 and 462′ can be formed by, for example but not limited to, a lithography process step and an ion implantation process step, wherein the lithography process step includes forming a photo-resist layer PR2 as a mask, and the ion implantation process step implants N-type conductivity impurities into the semiconductor layer 42 in the form of accelerated ions (as indicated by the dashed arrow in FIG. 5E), to form the third wells 462 and 462′.

Next, referring to FIG. 5F, first wells 461 and 461′ are formed in the semiconductor layer 42. In the semiconductor layer 42, the first wells 461 and 461′ encompass and contact the P-type region 45 which is to be formed in a later step. The first wells 461 and 461′ serve to electrically isolate the P-type region 45 and the first wells 461 and 461′ from the rest regions (other than the P-type region 45 and the first wells 461 and 461′) in the semiconductor layer 42. The first wells 461 and 461′ have N-type conductivity. The first wells 461 and 461′can be formed by, for example but not limited to, a lithography process step and an ion implantation process step, wherein the lithography process step includes forming a photo-resist layer PR3 as a mask, and the ion implantation process step implants P-type conductivity impurities into the semiconductor layer 42 in the form of accelerated ions (as indicated by the dashed arrow in FIG. 5F), to form the first wells 461 and 461′.

Still referring to FIG. 5F, isolation regions 44, 44′, 44a, 44a′, 44b, 44b′ are formed in the semiconductor layer 42. The isolation regions 44, 44′, 44a, 44a′, 44b, 44b′ are insulators and can be for example but not limited to a STI structure as shown in FIG. 5F, or may be a LOCOS structure or a CVD structure instead. Besides, from a top view, the isolation regions 44 and 44′ lie between the first wells 461 and 461′ and the second wells 451 and 451′; the isolation regions 44a and 44a′ lie between the second wells 451 and 451′ and the third wells 462 and 462′; the isolation regions 44b and 44b′ lie between the third wells 462 and 462′ and the fourth wells 452 and 452′.

Next, referring to FIG. 5G, polysilicon layers 47 and 47′ and a photo-resist layer PR4 are formed on the semiconductor layer to define a first implantation region, wherein the first implantation region serves to define the P-type region 45. The P-type region 45 can be formed by, for example but not limited to, a lithography process step and a first ion implantation process step, wherein the lithography process step includes adopting the photo-resist layer PR4 as a mask, and the first ion implantation process step implants P-type conductivity impurities into the first implantation region in the form of accelerated ions (as indicated by the dashed arrow in FIG. 5G), to form the P-type region 45. In this embodiment the polysilicon layers 47 and 47′ assist in defining the first implantation region. There can be a dielectric layer below the polysilicon layers 47 and 47′, as referring to the explanation regarding the polysilicon layer 27.

Next, referring to FIG. 5H, the polysilicon layers 47 and 47′ as shown in FIG. 5G are etched via an etching process step and a photo-resist layer PR5 is formed on the semiconductor layer 42, so as to define a second implantation region, wherein the second implantation region serves to define the N-type region 46. The N-type region 46 can be formed by, for example but not limited to, a lithography process step and a second ion implantation process step, wherein the lithography process step includes adopting the etched polysilicon layers 47 and 47′ and a photo-resist layer PR5 as a mask, and the second ion implantation process step implants N-type conductivity impurities into the second implantation region in the form of accelerated ions (as indicated by the dashed arrow in FIG. 5H), to form the N-type region 46.

Next, referring to FIG. 5I, the photo-resist layer PR5 is removed. And, spacer layers of the polysilicon layers 47 and 47′ are formed on the semiconductor layer, so as to form the Zener diode 400.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a silicon metal layer, may be added. For another example, the lithography technique is not limited to the mask technology but it can be electron beam lithography, immersion lithography, etc. Therefore, in the same spirit of the present invention, those skilled in the art can think of various equivalent variations and modifications, which should fall in the scope of the claims and the equivalents.

What is claimed is:

1. A Zener diode, comprising:
a semiconductor layer, which is formed on a substrate;
an N-type region having N-type conductivity, wherein the N-type region is formed in the semiconductor layer, wherein the N-type region is beneath and in contact with an upper surface of the semiconductor layer; and
a P-type region having P-type conductivity, wherein the P-type region is formed in the semiconductor layer, wherein the P-type region is completely beneath and in contact with the N-type region;
wherein the N-type region overlays the entire P-type region;
wherein an N-type conductivity dopant concentration of the N-type region is higher than a P-type conductivity dopant concentration of the P-type region.

2. The Zener diode of claim 1, further comprising:
a first well having N-type conductivity, wherein the first well is formed in the semiconductor layer, and wherein in the semiconductor layer, the first well encompasses and contacts the P-type region;
a second well having P-type conductivity, wherein the second well is formed in the semiconductor layer, and wherein in the semiconductor layer, the second well encompasses and contacts the first well; and
a deep well having P-type conductivity, wherein the deep well is formed in the semiconductor layer, and wherein the deep well is vertically beneath and in contact with the P-type region and the first well, and wherein a bottom of the P-type region and a bottom of the first well are entirely covered by the deep well from below.

3. The Zener diode of claim 2, further comprising:
a third well having N-type conductivity, wherein the third well is formed in the semiconductor layer, and wherein in the semiconductor layer, the third well encompasses and contacts the second well;
a fourth well having P-type conductivity, wherein the fourth well is formed in the semiconductor layer, and wherein in the semiconductor layer, the fourth well encompasses and contacts the third well; and
a buried layer having N-type conductivity, wherein the buried layer is formed in the semiconductor layer, and wherein the buried layer is vertically beneath and in contact with the deep well, the second well and the third well, and wherein a bottom of the deep well, a bottom of the second well and a bottom of the third well are entirely covered by the buried layer from below.

4. The Zener diode of claim 1, further comprising:
a polysilicon layer, which is formed on and in contact with the semiconductor layer, wherein the polysilicon layer serves to define the N-type region, wherein from a top view, the polysilicon layer encompasses the N-type region from outside.

5. The Zener diode of claim 2, further comprising:
an isolation region, which is formed in the semiconductor layer, wherein the isolation region is an insulator, and wherein from a top view, the isolation region lies between the first well and the second well.

6. A manufacturing method of a Zener diode, comprising:
forming a semiconductor layer on a substrate;
forming a P-type region in the semiconductor layer, wherein the P-type region has P-type conductivity;
forming an N-type region in the semiconductor layer, wherein the N-type region has N-type conductivity, wherein the N-type region is beneath and in contact with an upper surface of the semiconductor layer, and wherein the P-type region is completely beneath and in contact with the N-type region;
wherein the N-type region overlays the entire P-type region;
wherein an N-type conductivity dopant concentration of the N-type region is higher than a P-type conductivity dopant concentration of the P-type region.

7. The manufacturing method of the Zener diode of claim 6, further comprising:
forming a first well in the semiconductor layer, wherein the first well has N-type conductivity, and wherein in the semiconductor layer, the first well encompasses and contacts the P-type region;
forming a second well in the semiconductor layer, wherein the second well has P-type conductivity, and wherein in the semiconductor layer, the second well encompasses and contacts the first well; and
forming a deep well in the semiconductor layer, wherein the deep well is vertically beneath and in contact with the P-type region and the first well, wherein the deep well has P-type conductivity, and wherein a bottom of the P-type region and a bottom of the first well are entirely covered by the deep well from below.

8. The manufacturing method of the Zener diode of claim 7, further comprising:
forming a third well in the semiconductor layer, wherein the third well has N-type conductivity, and wherein in the semiconductor layer, the third well encompasses and contacts the second well;
forming a fourth well in the semiconductor layer, wherein the fourth well has P-type conductivity, and wherein in the semiconductor layer, the fourth well encompasses and contacts the third well; and
forming a buried layer in the semiconductor layer, wherein the buried layer is vertically beneath and in contact with the deep well, the second well and the third well, wherein the buried layer has N-type conductivity, and wherein a bottom of the deep well, a bottom of the second well and a bottom of the third well are entirely covered by the buried layer from below.

9. The manufacturing method of the Zener diode of claim 6, further comprising:
forming a polysilicon layer on the semiconductor layer, wherein the polysilicon layer is in contact with the semiconductor layer, and the polysilicon layer serves to define the N-type region, wherein from a top view, the polysilicon layer encompasses the N-type region from outside.

10. The manufacturing method of the Zener diode of claim 7, further comprising:
forming an isolation region in the semiconductor layer, wherein the isolation region is an insulator, and wherein from a top view, the isolation region lies between the first well and the second well.

11. The manufacturing method of the Zener diode of claim 6, wherein the step of forming the P-type region in the semiconductor layer includes:
forming a polysilicon layer, to define a first implantation region, wherein the first implantation region serves to define the P-type region; and
adopting the polysilicon layer as a mask, and implanting the P-type conductivity impurities into the first implantation region in the form of accelerated ions via a first ion implantation process step.

12. The manufacturing method of the Zener diode of claim 7, wherein the step of forming the N-type region in the semiconductor layer includes:
etching a polysilicon layer via an etching process step, to define a second implantation region, wherein the second implantation region serves to define the N-type region; and
adopting the etched polysilicon layer as a mask, and implanting the N-type conductivity impurities into the second implantation region in the form of accelerated ions via a second ion implantation process step.
